(19) United States
(12) Patent Application Publication
(10) Pub. No.: US 2025/0204181 A1
(43) Pub. Date: Jun. 19, 2025

(54) DISPLAY DEVICE

(71) Applicant: LG Display Co., Ltd., Seoul (KR)

(72) Inventors: KwangYong CHOI, Paju-si (KR); DongYoon LEE, Paju-si (KR); Insu HWANG, Paju-si (KR)

(21) Appl. No.: 18/937,894

(22) Filed: Nov. 5, 2024

(30) Foreign Application Priority Data
Dec. 15, 2023 (KR) 10-2023-0183645

(51) Int. Cl. H10K 59/131; H10K 59/38

(52) U.S. Cl. CPC H10K 59/131; H10K 59/38

(57) ABSTRACT

Embodiments of the present disclosure are related to a display device. A display device may include a substrate, a first metal on the substrate, a passivation layer on the first metal, a dam on the passivation layer, and a contact hole penetrating the dam and the passivation layer, so that it is possible to prevent the color filter layer from overflowing into the contact hole.

### CROSS REFERENCE TO RELATED APPLICATION

This application claims priority from Korean Patent Application No. 10-2023-0183645, filed on Dec. 15, 2023, which is hereby incorporated by reference for all purposes as if fully set forth herein.

### BACKGROUND

### Technical Field

Embodiments of the present disclosure relate to a display device.

### Description of the Related Art

As the information society develops, the demand for display devices for displaying images is increasing in various forms. In recent years, various display devices such as liquid crystal displays and organic light emitting display devices have been used.

A display panel may include a substrate, a driving transistor on the substrate, a light emission layer, a color filter, etc.

A source node of the driving transistor may be in contact with a pixel electrode through a contact hole, and the emission layer may emit light by receiving current from the pixel electrode.

After the color filter layer is disposed, an overcoat layer may be disposed on the top of the color filter layer.

### BRIEF SUMMARY

In the related art, the color filter layer may flow over the contact hole before the overcoat layer is disposed, in which case the contact problem may occur in a contact hole area. The inventors of the present disclosure recognized the various technical problems in the related art, including the above-identified problem. Various embodiments of the present disclosure address technical problems in the related art.

Embodiments of the present disclosure may provide a display device including a contact hole with stable contact characteristics.

Embodiments of the present disclosure may provide a display device including a color filter layer which does not overflow into the contact hole.

Embodiments of the present disclosure may provide a display device including a dam capable of preventing flooding of the color filter layer.

Embodiments of the present disclosure may provide a display device capable of low power consumption due to stable contact of the contact hole.

Embodiments of the present disclosure may provide a display device including a substrate, a first metal on the substrate, a passivation layer on the first metal, a dam on the passivation layer, and a contact hole extending into (in some embodiments, extending through and penetrating) the dam and the passivation layer.

According to embodiments of the present disclosure, it is possible to provide a display device including a contact hole with stable contact characteristics.

According to embodiments of the present disclosure, it is possible to provide a display device including a color filter layer which does not overflow into the contact hole.

According to embodiments of the present disclosure, it is possible to provide a display device including a dam capable of preventing flooding of the color filter layer.

According to embodiments of the present disclosure, it is possible to provide a display device capable of low power consumption due to stable contact of the contact hole.

### BRIEF DESCRIPTION OF THE SEVERAL VIEWS OF THE DRAWINGS

FIG. 1 illustrates a configuration diagram of a display device according to embodiments of the present disclosure.

FIG. 2 is an equivalent circuit of a subpixel of a display device according to embodiments of the present disclosure.

FIG. 3 is a plan view of a subpixel according to embodiments of the present disclosure.

FIGS. 4 to 10 are cross-sectional views of an area AB according to embodiments of the present disclosure.

FIGS. 11 and 12 are plan views of subpixels according to embodiments of the present disclosure.

FIG. 13 is a cross-sectional view of an area AB according to embodiments of the present disclosure.

FIG. 14 is a plan view of a subpixel according to embodiments of the present disclosure.

FIG. 15 is a cross-sectional view of an area AB according to embodiments of the present disclosure.

FIG. 16 is a plan view of a subpixel according to embodiments of the present disclosure.

FIG. 17 is a cross-sectional view of an area AB according to embodiments of the present disclosure.

FIG. 18 is a plan view of a subpixel according to embodiments of the present disclosure.

FIGS. 19 to 23 are diagrams for explaining a subpixel forming process according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),”, or “(B)” may be used herein to describe elements of the present disclosure. Each of these terms is not used to define essence, order, sequence, or number of elements, etc., but is used merely to distinguish the corresponding element from other elements.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other. For example, unless preceded by “directly,” the term “contact” does not necessarily mean “direct contact” and may also include indirect contact.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, it will be described in detail embodiments of the present disclosure with reference to the attached drawings.

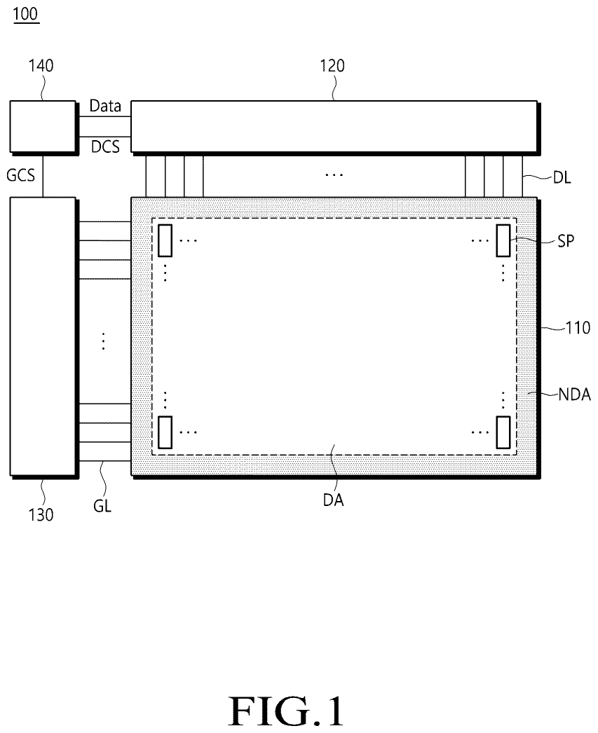

FIG. 1 illustrates a system configuration diagram of a display device 100 according to embodiments of the present disclosure.

Referring to FIG. 1, a display device 100 according to embodiments of the present disclosure may include a display panel 100, and a driving circuit for driving the display panel 110.

The display panel 110 may include signal lines such as a plurality of data lines DL and a plurality of gate lines GL, and may include a plurality of subpixels SP. The display panel 110 may include a display area DA where an image is displayed and a non-display area NDA where an image is not displayed. In the display panel 110, a plurality of subpixels SP for displaying an image may be disposed in the display area DA. In the non-display area NDA, the driving circuits 120, 130 and 140 may be electrically connected or the driving circuits 120, 130, and 140 may be mounted, and there may be a pad portion to which an integrated circuit or printed circuit is connected.

The driving circuit may include a data driving circuit 120 and a gate driving circuit 130, and may further include a controller 140 which controls the data driving circuit 120 and the gate driving circuit 130.

The data driving circuit 120 is a circuit for driving a plurality of data lines DL, and may supply data signals to the plurality of data lines DL. The gate driving circuit 130 is a circuit for driving a plurality of gate lines GL, and may supply gate signals to the plurality of gate lines GL.

The gate driving circuit 130 may output a gate signal of a turn-on level voltage or a gate signal of a turn-off level voltage according to the control of the controller 140. The gate driving circuit 130 may sequentially drive a plurality of gate lines GL by sequentially supplying a gate signal with a turn-on level voltage to the plurality of gate lines GL.

The controller 140 may supply a data control signal DCS to the data driving circuit 120 to control the operation timing of the data driving circuit 120. The controller 140 may supply a gate control signal GCS to the gate driving circuit 130 to control the operation timing of the gate driving circuit 130.

The controller 140 may start scanning according to the timing implemented in each frame, may convert the input image data input from the outside to fit the data signal format used in the data driving circuit 120 to output the converted image data DATA, and may control data operation at an appropriate time according to the scan.

In order to control the data driving circuit 120 and the gate driving circuit 130, the controller 140 may receive various timing signals including a vertical synchronization signal Vsync, a horizontal synchronization signal Hsync, an input data enable DE signal, a clock signal CLK, and may generate various control signals DCS and GCS and outputs the control signals to the data driving circuit 120 and the gate driving circuit 130.

The controller 140 may be implemented as a separate component from the data driving circuit 120, or may be integrated with the data driving circuit 120 and implemented as an integrated circuit.

The data driving circuit 120 may receive image data DATA from the controller 140 and supply a data voltage to the plurality of data lines DL, thereby driving the plurality of data lines DL. Here, the data driving circuit 120 may be also referred to as a source driving circuit. The data driving circuit 120 may include one or more source driver integrated circuits (SDIC). Each source driver integrated circuit S-DIC may include a shift register, a latch circuit, a digital-to-analog converter, and an output buffer. Each source driver integrated circuit S-DIC may, in some cases, further include an analog to digital converter ADC.

For example, each source driver integrated circuit S-DIC may be connected to a bonding pad of the display panel 110 using a tape automated bonding (TAB) method or a chip-on-glass (COG) method or a chip-on-panel (COP) method. Alternatively, each source driver integrated circuit (SDIC) may be directly disposed on the display panel 110. Alternatively, each source driver integrated circuit S-DIC may be integrated and disposed on the display panel 110. Alternatively, each source driver integrated circuit S-DIC may be implemented in a chip on film (COF) method.

The gate driving circuit 130 may be connected to a bonding pad of the display panel 110 using a chip-on-glass (COG) method or a chip-on-panel (COP) method, or may be implemented as a gate-in-panel (GIP) type and placed directly on the display panel 110, or may be integrated and disposed on the display panel 110 in some cases. Alternatively, the gate driving circuit 130 may be implemented using a chip-on-film (COF) method in which a plurality of gate driver integrated circuits (G-DICs) are implemented and mounted on a gate-circuit film connected to the display panel 110.

When a specific gate line is opened by the gate driving circuit 130, the data driving circuit 120 may convert the image data DATA received from the controller 140 into an analog data voltage to supply to a plurality of data lines DL.

The data driving circuit 120 may be located only on one side (e.g., upper or lower side) of the display panel 110, and in some cases, the data driving circuit 120 may be located on both sides (e.g., upper and lower sides) of the display panel 110 depending on the driving method, panel design method, etc.

The gate driving circuit 130 may be located only on one side (e.g., left or right side) of the display panel 110, and in some cases, the gate driving circuit 130 may be located on both sides (e.g., left and right sides) of the display panel 110 depending on the driving method, panel design method, etc.

The controller 140 may be a timing controller used in typical display technology, or may be a control device capable of further performing other control functions including a timing controller, or may be a control device different from the timing controller, or may be a control device other than a timing controller, or may be a circuit within the control device. The controller 140 may be implemented with various circuits or electronic components, such as an integrated circuit (IC), a field programmable gate array (FPGA), an application specific integrated circuit (ASIC), or Processor.

The controller 140 may be mounted on a printed circuit board, a flexible printed circuit, etc., and may be electrically connected to the data driving circuit 120 and the gate driving circuit 130 through a printed circuit board, a flexible printed circuit. The controller 140 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI). The controller 140 may include a storage means such as one or more registers.

The display device 100 according to the present embodiments may be a self-luminous display such as an organic light emitting diode (OLED) display, a quantum dot display, or a micro light emitting diode (Micro LED) display.

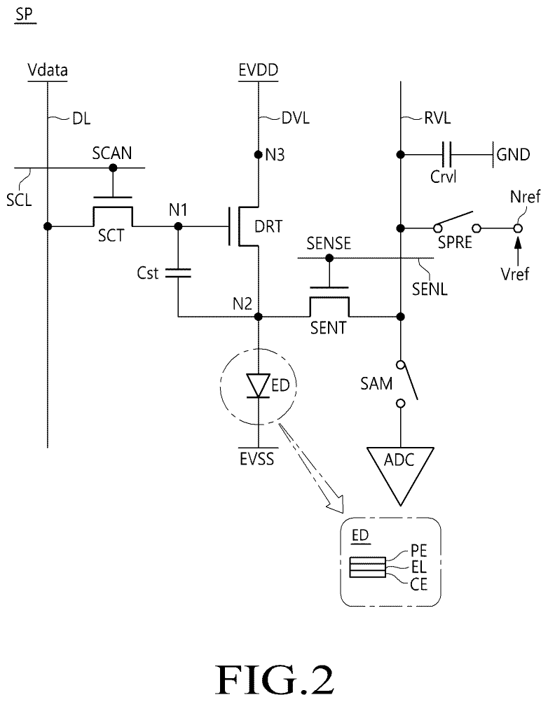

FIG. 2 is an equivalent circuit of a subpixel of a display device according to embodiments of the present disclosure.

Referring to FIG. 2, each of the plurality of subpixels SP disposed on the display panel 110 of the display device 100 according to embodiments of the present disclosure may include a light emitting element ED, a driving transistor DRT, a scan transistor SCT, a sensing transistor SENT, and a storage capacitor Cst. Accordingly, in the case that the subpixel SP includes three transistors DRT, SCT and SENT, and one capacitor Cst, the subpixel SP may be said to have a 3T (Transistor) 1C (Capacitor) structure.

The light emitting device ED may include a pixel electrode PE and a common electrode CE, and an emission layer EL located between the pixel electrode PE and the common electrode CE. Here, the pixel electrode PE may be disposed in each subpixel SP, and the common electrode CE may be commonly disposed in a plurality of subpixels SP. For example, the pixel electrode PE may be an anode electrode, and the common electrode CE may be a cathode electrode. For another example, the pixel electrode PE may be a cathode electrode, and the common electrode CE may be an anode electrode. For example, the light emitting device ED may be an organic light emitting diode (OLED), a micro light emitting diode (micro LED), or a quantum dot light emitting device.

The driving transistor DRT is a transistor for driving the light emitting device ED, and may include a first node N1, a second node N2, and a third node N3.

The first node N1 of the driving transistor DRT may be a gate node of the driving transistor DRT, and may be electrically connected to a source node or drain node of the scan transistor SCT. The second node N2 of the driving transistor DRT may be a source node or drain node of the driving transistor DRT, may be electrically connected to the source node or drain node of the sensing transistor SENT, and may also be electrically connected to the pixel electrode PE of the light emitting device ED. The third node N3 of the driving transistor DRT may be electrically connected to a driving voltage line DVL for supplying a driving voltage EVDD.

The scan transistor SCT may be controlled by the scan signal SCAN, and may be connected between the first node N1 of the driving transistor DRT and a data line DL. The scan transistor SCT may be turned on or off according to a scan signal SCAN supplied from a scan signal line SCL, which is a type of gate line GL, and may control the connection between the data line DL and the first node N1 of the driving transistor DRT.

The scan transistor SCT may be turned on by the scan signal SCAN having a turn-on level voltage, and transfer the image data voltage Vdata supplied from the data line DL to the first node N1 of the driving transistor DRT.

The turn-on level voltage of the scan signal SCAN for turning on the scan transistor SCT may be a high-level voltage or a low-level voltage. The turn-off level voltage of the scan signal SCAN for turning off the scan transistor SCT may be a low-level voltage or a high-level voltage. For example, if the scan transistor SCT is an n-type transistor, the turn-on level voltage may be a high-level voltage and the turn-off level voltage may be a low-level voltage. For another example, if the scan transistor SCT is a p-type transistor, the turn-on level voltage may be a low-level voltage and the turn-off level voltage may be a high-level voltage.

The sensing transistor SENT may be controlled by a sense signal SENSE, and may be connected between the second node N2 of the driving transistor DRT and a reference voltage line RVL. The sensing transistor SENT may be turned on or turned off according to the sense signal SENSE supplied from a sense signal line SENL, which is another type of gate line GL, and may may control the connection between the reference voltage line RVL and the second node N2 of the driving transistor DRT.

The sensing transistor SENT may be turned on by the sense signal SENSE having a turn-on level voltage, and may transfer a reference voltage Vref supplied from the reference voltage line RVL to the second node N2 of the driving transistor DRT.

The turn-on level voltage of the sense signal SENSE for turning on the sensing transistor SENT may be a high-level voltage or a low-level voltage. The turn-off level voltage of the sense signal SENSE for turning off the sensing transistor SENT may be a low-level voltage or a high-level voltage. For example, if the sensing transistor SENT is an n-type transistor, the turn-on level voltage may be a high-level voltage and the turn-off level voltage may be a low-level voltage. For another example, if the sensing transistor SENT is a p-type transistor, the turn-on level voltage may be a low-level voltage and the turn-off level voltage may be a high-level voltage.

Meanwhile, the display device 100 may further include a line capacitor Crvl formed between the reference voltage line RVL and a ground GND, a sampling switch SAM for controlling the connection between the reference voltage line RVL and the analog-to-digital converter ADC, and a power switch SPRE for controlling the connection between the reference voltage line RVL and a reference voltage supply node Nref. The reference voltage Vref output from a power supply device may be supplied to the reference voltage supply node Nref and to the reference voltage line RVL through the power switch SPRE.

In addition, the sensing transistor SENT may be turned on by the sense signal SENSE having a turn-on level voltage, and may transfer a voltage V2 of the second node N2 of the driving transistor DRT to the reference voltage line RVL. Accordingly, the line capacitor Crvl formed between the reference voltage line RVL and the ground GND may be charged.

The function of the sensing transistor SENT to transfer the voltage V2 of the second node N2 of the driving transistor DRT to the reference voltage line RVL may be used when driving to sense the characteristics of the subpixel SP. In this case, the voltage transferred to the reference voltage line VREFL may be a voltage for calculating the characteristic value of the subpixel SP or a voltage reflecting the characteristic value of the subpixel SP.

In the present disclosure, the characteristic value of the subpixel SP may be the characteristic value of the driving transistor DRT or the light emitting device ED. For example, the characteristic values of the driving transistor DRT may include a threshold voltage and a mobility of the driving transistor DRT. The characteristic value of the light emitting device ED may include a threshold voltage of the light emitting device ED.

The driving transistor DRT, scan transistor SCT, and sensing transistor SENT may each be an n-type transistor or a p-type transistor. In this disclosure, for convenience of explanation, it is exemplified that the driving transistor DRT, scan transistor SCT, and sensing transistor SENT are each n-type.

The storage capacitor Cst may be electrically connected between the first node N1 and the second node N2 of the driving transistor DRT. The storage capacitor Cst may be charged with a charge corresponding to the voltage difference between both ends and acts to maintain the voltage difference between both ends for a set frame time. Accordingly, the corresponding subpixel SP may emit light during a set frame time.

The storage capacitor Cst may be an external capacitor intentionally designed outside the driving transistor DT rather than a parasitic capacitor (e.g., Cgs, Cgd) as an internal capacitor which may exist between a gate node and a source node (or a drain node) of the driving transistor DRT.

The scan signal line SCL and sense signal line SENL may be different gate lines GL. In this case, the scan signal SCAN and the sense signal SENSE may be separate gate signals, and the on-off timing of the scan transistor SCT and the on-off timing of the sensing transistor SENT within one subpixel SP may be independent. That is, the on-off timing of the scan transistor SCT and the on-off timing of the sensing transistor SENT within one subpixel SP may be the same or different.

Alternatively, the scan signal line SCL and the sense signal line SENL may be the same gate line GL. That is, the gate node of the scan transistor SCT and the gate node of the sensing transistor SENT within one subpixel SP may be connected to one gate line GL. In this case, the scan signal SCAN and the sense signal SENSE may be the same gate signal, and the on-off timing of the scan transistor SCT and the on-off timing of the sensing transistor SENT within one subpixel SP may be the same.

Meanwhile, the reference voltage line RVL may be arranged in each subpixel SP column. Alternatively, the reference voltage line RVL may be disposed in every column of two or more subpixels SP. If the reference voltage line RVL is disposed in each column of two or more subpixels SP, the plurality of subpixels SP may receive the reference voltage Vref from one reference voltage line RVL.

In the above, there has been described the equivalent circuit of the subpixel, and hereinafter, it will be described a structure of the subpixel through a plan view and a cross-sectional view.

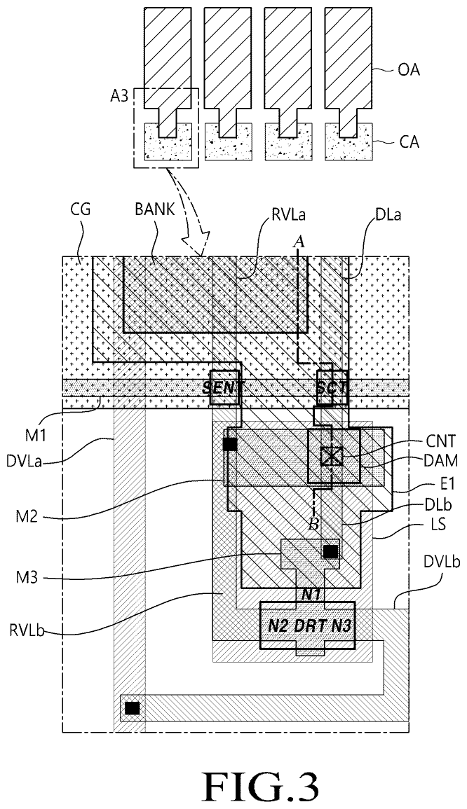

FIG. 3 is a plan view of a subpixel SP according to embodiments of the present disclosure.

Referring to FIG. 3, there is illustrated an example diagram of a subpixel SP.

One subpixel SP may include an opening area OA and a circuit area CA.

The opening area OA may be an area where light is emitted. The opening area OA

may include an area where light is emitted, and the opening area OA may include a light emitting device and electrodes electrically connected to the light emitting device.

The circuit area CA may be an area where circuits for controlling the light emitting device are disposed.

Referring to FIG. 3, there is illustrated an enlarged area A3 for the opening area OA and the circuit area CA.

Referring to FIG. 3, a plurality of lines, electrodes, contact holes CNTs may be disposed on the substrate.

The substrate may include a plurality of driving transistors DRT, a plurality of scan transistors SCT, and a plurality of sensing transistors SENT.

Referring to FIG. 3, a first driving voltage line DVLa and a light blocking layer LS may be disposed on the substrate.

The first driving voltage line DVLa may be disposed on the left side of the enlarged area A3. The first driving voltage line DVLa may be disposed to extend in a vertical direction.

The first driving voltage line DVLa may be electrically connected to a second driving voltage line DVLb.

The light blocking layer LS may be a layer where the driving transistor DRT is disposed. Therefore, the first node N1, the second node N, and the third node of the driving transistor DRT may be located on the light blocking layer LS.

The second driving voltage line DVLb may be disposed on the substrate and the light blocking layer LS. The second driving voltage line DVLb may be electrically connected to the third node N3 of the driving transistor DRT on the light blocking layer LS.

The sensing transistor SENT may be disposed between a first reference voltage line RVLa and a second reference voltage line RVLb. The second reference voltage line DVLb may be electrically connected to the second node N2 on the light blocking layer LS. The first reference voltage line RVLa and the second reference voltage line DVLb may be arranged to extend in the vertical direction.

The scan transistor SCT may be disposed between a first data line DLa and a second data line DLb. The second data line DLb may be electrically connected to a third gate metal M3 on the light blocking layer LS. The signal transmitted through the second data line DLb may be supplied to the first node N1, which is the gate node of the driving transistor DRT, through the third gate metal M3. The first data line DLa and the second data line DLb may be disposed to extend in the vertical direction.

A first gate metal M1 may be disposed on the gate nodes of the sensing transistor SENT and the scan transistor SCT. The first gate metal M1 may be a gate line. When a gate signal is supplied to the first gate metal M1, the scan transistor SCT and the sensing transistor SENT may be turned on. Referring to FIG. 3, the scan transistor SCT and the sensing transistor SENT may share the same gate line, which can be referred to as a one-scan structure. However, if a gate line other than the gate line shown in FIG. 3 is added, the scan transistor SCT and the sensing transistor SENT may be controlled separately, which can be referred to as a two-scan structure. The first gate metal M1 may be disposed to extend in the horizontal direction.

A second gate metal M2 may be disposed on the light blocking layer LS. The second gate metal M2 may be electrically connected to the second node N2. The second gate metal M2 may have a flat shape. The second gate metal M2 may be configured as a storage capacitor together with another metal layer formed under the second gate metal M2.

A third gate metal M3 may be disposed on the light blocking layer LS. The third gate metal M3 may be electrically connected to the first node N1, which is the gate node of the driving transistor DRT. The third gate metal M3 may be arranged to extend in the vertical direction. Although not shown in FIG. 3, an active layer may be disposed below the third gate metal M3. The active layer may be bimetallic. The active layer may have a double metal structure in which a first metal of a common metal and a second metal such as IGZO overlap.

A dam DAM may be disposed on the second gate metal M2. The dam DAM may be disposed to surround a contact hole CNT. The dam DAM may be rectangular shape, and in some cases, the dam DAM may be polygonal or circular.

The contact hole CNT may be an area where the second gate metal M2 and the pixel electrode are electrically connected. A contact hole CNT area may be in the form of a hole through which the second gate metal M2 and the pixel electrode can be electrically connected. The contact hole CNT may have a reverse taper shape. The side surface of the contact hole CNT may have a certain slope, and a portion of the side surface of the contact hole CNT may have a step shape. Additionally, the side surface of the contact hole CNT may have a curved slope.

A color filter layer CF may be disposed to cover the opening area OA on the substrate. The color filter layer CF may be disposed below the emission layer. In this case, the light emission method of the display device may be referred to as a bottom emission method. Referring to FIG. 3, there is illustrated as a case in which the color filter layer CF is disposed only in the opening area OA, but the color filter layer CF may also be disposed in the circuit area CA. In the case that the color filter layer CF is disposed in the circuit area CA, the color filter layer CF disposed in the circuit area CA may prevent parasitic capacitance from occurring between circuits disposed on the top and bottom of the color filter layer CF.

A pixel electrode may be disposed in contact with the second gate metal M2 in the contact hole CNT. The pixel electrode may be disposed on the light blocking layer LS, and the color filter layer CF.

A bank layer may be disposed on the pixel electrode. A bank layer area BANK corresponding to the opening area OA may be removed. Although the bank layer is shown in FIG. 3 as being arranged, the bank layer may not be formed depending on the design.

Although not shown in FIG. 3, the emission layer may be disposed on the pixel electrode. A common electrode may be disposed on the emission layer.

Meanwhile, the color filter layer CF may be formed before the pixel electrode. If there is no dam DAM, the color filter layer CF can flow to the area of the contact hole CNT. In this case, the pixel electrode may be in abnormal contact with the second gate metal M2 in the area of the contact hole CNT. To prevent this, the color filter layer CF may be disposed at a specific distance or more from the contact hole CNT.

However, if the dam DAM is formed before forming the color filter layer CF, the color filter layer CF may not overflow into the contact hole CNT due to the dam DAM. That is, if the dam DAM is formed, the design of the color filter layer CF can become easier.

That is, embodiments of the present disclosure may provide a display device including a contact hole with the stable contact characteristics.

Embodiments of the present disclosure may provide a display device including a color filter layer which does not overflow into the contact hole.

Embodiments of the present disclosure may provide a display device including a dam capable of preventing flooding of the color filter layer.

Embodiments of the present disclosure may provide a display device capable of low power consumption by stably contacting the contact hole.

FIG. 3 illustrates a plan view of an area AB area. Hereinafter, it will be described a cross-sectional structure of area AB shown in FIG. 3.

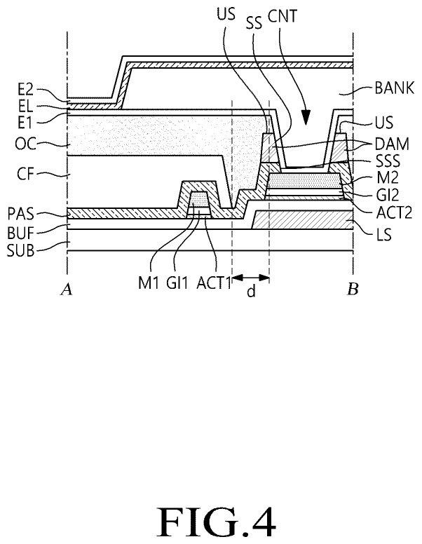

FIGS. 4 to 13 are cross-sectional views of an area AB according to embodiments of the present disclosure.

Referring to FIG. 4, there is illustrated a cross-sectional view of an area AB.

Referring to FIG. 4, the substrate SUB may be disposed at the bottom or a lowest portion of the display panel 110. The substrate SUB may be a rigid material or a bendable material.

Referring to FIGS. 3 and 4, the light blocking layer LS may be disposed on the substrate SUB. The light blocking layer LS may be made of a metal material, and may prevent external light from penetrating into the circuit area CA. In addition, the light blocking layer LS may be used together with other electrodes to form a storage capacitor.

A buffer layer may be disposed to cover the substrate SUB and the light blocking layer LS. The buffer layer BUF may be a layer for electrical insulation.

Referring to FIGS. 3 and 4, a first active metal ACT1 may be disposed on the buffer layer BUF. The first active metal ACT1 may be disposed on the left side in FIG. 4. The first active metal ACT1 may be an active layer of the scan transistor SCT.

Referring to FIGS. 3 and 4, a second active metal ACT2 may be disposed on the buffer layer BUF. The second active metal ACT2 may be disposed on the right side in FIG. 4. The second active metal ACT2 may be disposed to overlap the light blocking layer LS. The second active metal ACT2 may be disposed to overlap a source node of the driving transistor DRT.

A first gate insulating layer GI1 may be disposed on the first active metal ACT1. The first gate insulating layer GI1 may be a layer for electrical insulation.

A second gate insulating layer GI2 may be disposed on the second active metal ACT2. The second gate insulating layer GI2 may be a layer for electrical insulation.

Referring to FIGS. 3 and 4, a first gate metal M1 may be disposed on the first gate insulating layer GI1. The first gate metal M1 may be the gate electrode of the scan transistor SCT.

Referring to FIGS. 3 and 4, a second gate metal M2 may be disposed on the second gate insulating layer GI2. The second gate metal M2 may be electrically connected to the source node of the transistor. That is, the second gate metal M2 may be electrically connected to the second node N2.

A passivation layer PAS may be disposed to cover the first gate metal M1 and the second gate metal M2. The passivation layer PAS may be a layer for electrical insulation.

A dam DAM may be disposed on the passivation layer PAS. The dam DAM disposed on the passivation layer PAS may be disposed in an area which overlaps the second active metal ACT2 or the second gate metal M2. The higher the height of the dam DAM, the easier it is to prevent the color filter layer CF from overflowing. The height of the dam DAM may be changed depending on the design.

A contact hole CNT may be an area extending into (in some embodiments, extending through and penetrating) the passivation layer PAS and the dam DAM. Therefore, the passivation layer PAS and the dam DAM may have a have a shape in which a central area is carved out.

A color filter layer CF may be disposed on the passivation layer PAS. The color filter layer CF disposed on the passivation layer PAS may be disposed to overlap the first gate metal M1. The dam DAM may be disposed to be spaced apart from the color filter layer CF.

An overcoat layer OC may be disposed to cover the color filter layer CF, the dam DAM, and the passivation layer PAS. The overcoat layer OC corresponding to the contact hole CNT may be etched and removed. Referring to FIG. 4, there is illustrated a case in which the overcoat layer OC is formed to only contact the upper surface US of the dam DAM. However, unlike FIG. 4, the overcoat layer OC may be formed to cover all sides of the dam DAM.

A pixel electrode may be disposed on the overcoat layer OC. The pixel electrode E1 may be disposed in contact with the second gate metal M2 in the contact hole CNT. The pixel electrode E1 may be electrically connected to the second gate metal M2 in the contact hole CNT.

A bank layer BANK may be disposed on the pixel electrode E1. Referring to FIGS. 3 and 4, the bank layer BANK may be removed by etching an area corresponding to the opening area OA.

An emission layer EL may be disposed on the pixel electrode E1. The emission layer EL may emit light by receiving current supplied through the pixel electrode E1.

A common electrode E2 may be disposed on the emission layer EL. The common electrode E2 may be disposed by being entirely deposited on the emission layer EL.

Referring to FIG. 4, the dam DAM may be disposed to surround the area of the contact hole CNT. Since the dam DAM is disposed to surround the area of the contact hole CNT, the color filter layer CF may not overflow into the area of the contact hole CNT. Accordingly, the pixel electrode E1 and the second gate metal M2 can be firmly coupled.

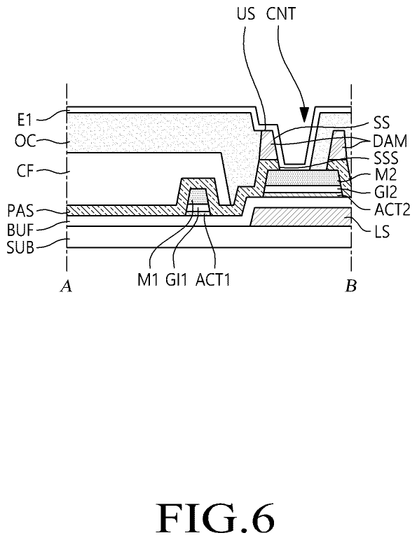

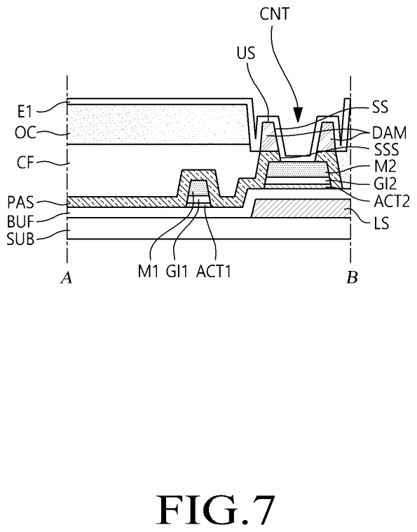

Referring to FIG. 4, there is illustrated a separation distance d between the lower right end of the color filter layer CF and the contact hole CNT of the overcoat layer OC. The design of the separation distance d may be freed due to the presence of the dam DAM. Referring to FIG. 4, the color filter layer CF is disposed to be spaced apart from the dam DAM. However, as shown in FIGS. 6 and 7, the color filter layer CF may be disposed in contact with or close to the dam DAM. For example, if there is no dam DAM, the separation distance d may need to be set greater than 20 um. However, if there is a dam DAM, the separation distance d may be reduced to 5 um.

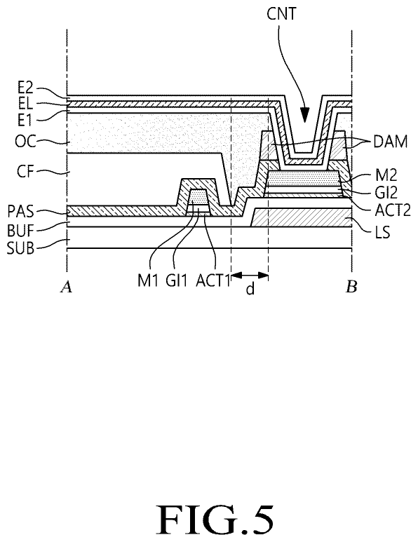

FIG. 5 illustrates another cross-sectional view of the area AB.

Referring to FIGS. 4 and 5, the bank layer BANK is not formed on the contact hole CNT shown in FIG. 5. The bank layer BANK may be not formed in the contact hole CNT shown in FIG. 5, and the emission layer EL may be disposed on the pixel electrode E1.

FIGS. 4 and 5 may be diagrams of the case where the contact hole CNT is most ideally formed. That is, if the contact hole CNT is formed ideally, the contact hole area may be cup-shaped with a constant slope. However, if the contact hole CNT is not formed ideally, the contact hole area may have a stepped shape or a curved inclined shape. It will be described a case where the contact hole CNT is not formed ideally with reference to FIGS. 6 to 10.

The dam DAM shown in FIGS. 6 and 7 may be formed of a different material from the overcoat layer OC.

After the overcoat layer OC is formed, the overcoat layer OC corresponding to the contact hole area may be etched and removed. If the etching process location for the overcoat layer OC is offset, some of the sides of the overcoat layer OC may be etched in a step shape or hill shape.

Referring to FIG. 6, there can be seen that the contact hole CNT is formed in a step shape on the left area of the dam DAM. Therefore, the pixel electrode E1 may be disposed in contact with an upper surface US of the dam DAM. The pixel electrode E1 may be formed in a step shape on the left side of the contact hole CNT. In this case, since the material of the dam DAM is different from the material of the overcoat layer OC, the dam DAM may be not etched when etching the overcoat layer OC. A portion of the dam DAM may be disposed so that both sides are covered by the overcoat layer OC.

Meanwhile, the contact hole CNT may also be formed on the right area of the dam DAM. Therefore, the pixel electrode E1 may be disposed in contact with the upper surface of the dam DAM. The pixel electrode E1 may be formed in steps on the right side of the contact hole CNT. In this case, since the material of the dam DAM is different from the material of the overcoat layer OC, the dam DAM may be not etched when etching the overcoat layer OC. A portion of the dam DAM may be disposed so that both sides are covered by the overcoat layer OC.

Referring to FIG. 7, there can be seen that the contact hole area of the overcoat layer OC is formed to be relatively large. The contact hole CNT in the overcoat layer OC may be larger than the size of the contact hole CNT in the central part of the dam DAM. The contact hole CNT in the central part of the dam DAM and the contact hole CNT in the overcoat layer OC may be areas for contact between the pixel electrode E1 and the second gate metal M2.

If the contact hole CNT in the overcoat layer OC is larger than the size of the contact hole CNT in the central part of the dam DAM, the dam DAM may be disposed to be spaced apart from the overcoat layer OC. That is, all of the overcoat layer OC surrounding the dam DAM may be etched and removed. At this time, since the overcoat layer OC and the dam DAM are made of different materials, the dam DAM may not be etched.

Referring to FIG. 7, the pixel electrode E1 may be disposed to cover the upper surface US and side surface SS of the dam DAM. Since the pixel electrode E1 is disposed on an upper portion of the overcoat layer OC and the dam DAM, the pixel electrode E1 may have a shape similar to a portion in contact with the overcoat layer OC and the dam DAM.

Referring to FIG. 7, a portion of the color filter layer CF may be etched in the process of forming the contact hole CNT of the overcoat layer OC. However, the color filter layer CF may not be etched.

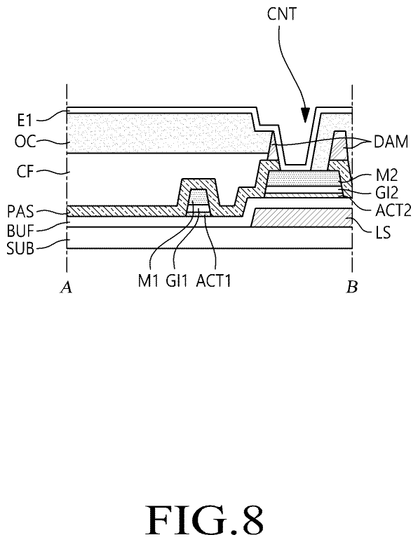

The dam DAM shown in FIGS. 8, 9, and 10 may be formed of the same material as the overcoat layer OC. That is, at least one material included in the dam DAM may be included in the overcoat layer OC.

After the overcoat layer OC is formed, the overcoat layer OC corresponding to the contact hole area may be etched and removed. If the etching process location for the overcoat layer OC is offset, some of the sides of the overcoat layer OC may be etched in a step shape or hill shape.

Referring to FIG. 8, there can be seen that the contact hole CNT is also formed on the left area of the dam DAM. Therefore, the pixel electrode E1 may be disposed in contact with the upper surface of the dam DAM. The pixel electrode E1 may be formed in steps on the left side of the contact hole CNT. In this case, since the material of the dam DAM is the same as the material of the overcoat layer OC, the dam DAM may also be etched when the overcoat layer OC is etched. A portion of the dam DAM may be disposed so that both sides are covered by the overcoat layer OC.

Meanwhile, the contact hole CNT may also be formed on the right area of the dam DAM. Therefore, the pixel electrode E1 may be disposed in contact with the upper surface of the dam DAM. The pixel electrode E1 may be formed in steps on the right side of the contact hole CNT. In this case, since the material of the dam DAM is the same as the material of the overcoat layer OC, the dam DAM may also be etched when the overcoat layer OC is etched. A portion of the dam DAM may be disposed so that both sides are covered by the overcoat layer OC.

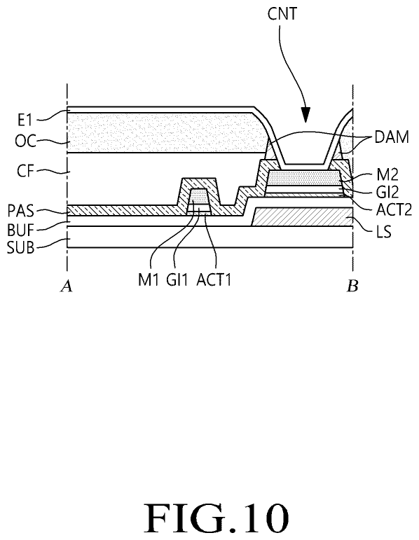

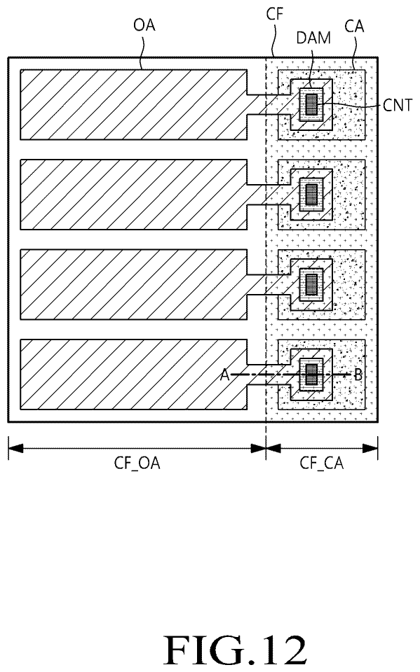

Referring to FIGS. 12 and 10, there can be seen that the contact hole area of the overcoat layer OC is formed to be relatively large. The contact hole CNT in the overcoat layer OC may be larger than the size of the contact hole CNT in the central part of the dam DAM. The contact hole CNT in the central part of the dam DAM and the contact hole CNT in the overcoat layer OC may be areas for contact between the pixel electrode E1 and the second gate metal M2.

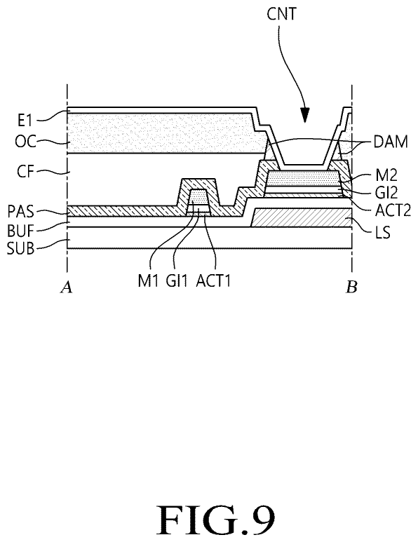

Referring to FIGS. 9 and 10, since the overcoat layer OC and the dam DAM are etched in the same etching process, the side of the overcoat layer OC and the side of the dam DAM may correspond to the contact hole area. The contact hole area may include an area extending from the side of the dam DAM to the side of the overcoat layer OC.

Referring to FIG. 9, the pixel electrode E1 may be disposed in steps on the overcoat layer OC. The pixel electrode E1 may be disposed in a step shape covering the side of the overcoat layer OC and the side of the dam DAM.

Referring to FIG. 10, the pixel electrode E1 may be disposed in a gently curved shape on the overcoat layer OC. The pixel electrode E1 may be arranged in a hill shape covering the side of the overcoat layer OC and the side of the dam DAM.

Since the pixel electrode E1 is disposed on the top or an upper portion of the overcoat layer OC and the dam DAM, the pixel electrode E1 may have a shape similar to the portion in contact with the overcoat layer OC and the dam DAM.

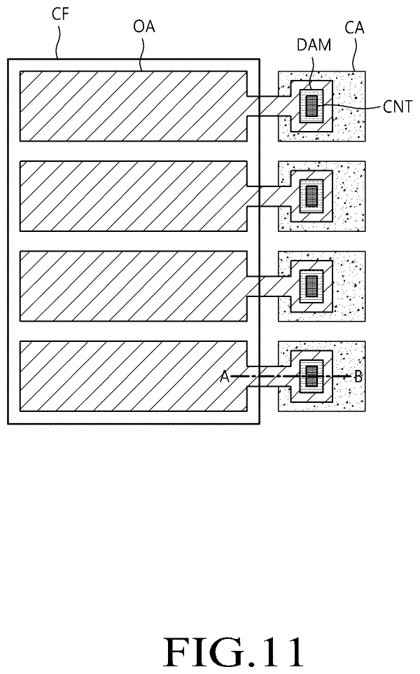

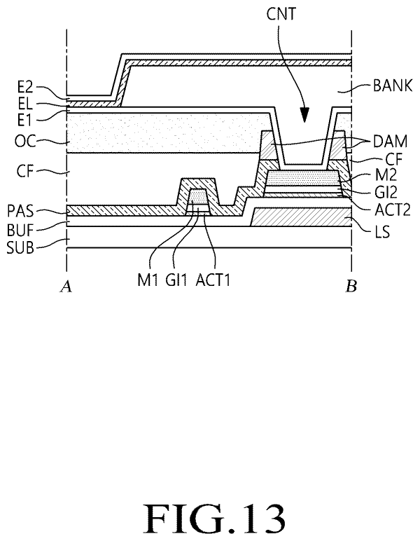

FIGS. 11 and 12 are plan views of the subpixel SP according to embodiments of the present disclosure. FIG. 13 is a cross-sectional view of the area AB according to embodiments of the present disclosure.

The substrate SUB may include a plurality of subpixels SP. Referring to FIG. 11, there is illustrated a case in which four subpixels SP are disposed.

Referring to FIG. 11, the subpixel SP may include an opening area OA and a circuit area CA. The circuit area CA may include a contact hole CNT and a dam DAM. Referring to FIG. 3, there is illustrated a dam DAM for one subpixel SP. Referring to FIG. 11, there is illustrated the dam DAM for each of the four subpixels SP. Referring to FIG. 11, the color filter layer CF may be disposed in the opening area OA.

Referring to FIG. 12, the color filter layer CF may be disposed to surround the dam DAM. The color filter layer CF may be disposed in contact with the dam DAM. In addition, in order to stably prevent the color filter layer CF from overflowing into the contact hole CNT, the color filter layer CF may be disposed at a specific distance from the dam DAM.

Referring to FIG. 12, the color filter layer CF may include a first color filter layer portion CF_OA disposed in the opening area OA and a second color filter layer portion CF_CA disposed in the circuit area CA. The color filter layer CF may be formed integrally. Additionally, a process for the color filter layer CF may be completed by disposing the second color filter layer CF_CA after disposing the first color filter layer CF_OA. The color filter layer CF_CA disposed in the circuit area CA may prevent parasitic capacitance from occurring between circuits disposed above and below the color filter layer CF.

Referring to FIG. 12, there can be seen the areas A-B in the plan view shown in FIG. 12. FIG. 13 illustrates a cross-sectional view of the area A-B. Referring to FIG. 13, the color filter layer CF may be disposed around the dam DAM. The dam DAM may be disposed in contact with the color filter layer CF.

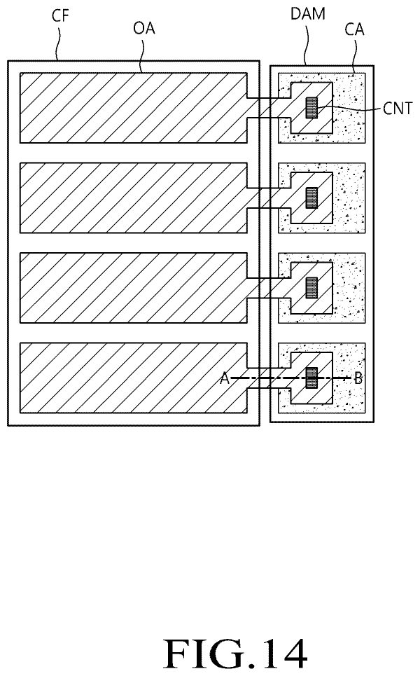

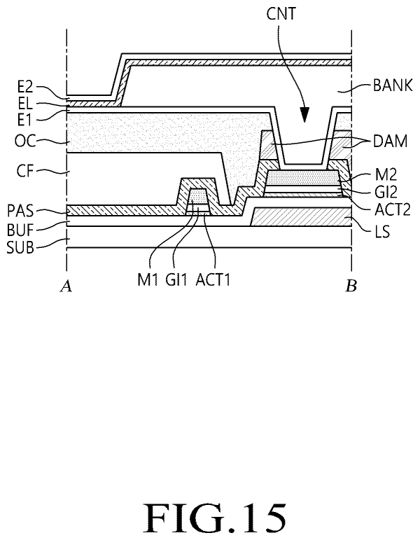

FIG. 14 is a plan view of the subpixel SP according to embodiments of the present disclosure. FIG. 15 is a cross-sectional view of the area AB according to embodiments of the present disclosure.

Referring to FIG. 14, a dam DAM may be disposed to cover four subpixels.

Specifically, the dam DAM may be disposed in an area excluding the contact hole CNT where the pixel electrodes E1 of the four subpixels are disposed. Referring to FIG. 14, there is illustrated that four holes are arranged in one dam DAM. The four holes may correspond to contact holes CNTs of each of the four subpixels. In FIGS. 11 and 12, there is illustrated that a dam DAM is disposed in each subpixel. However, referring to FIG. 14, one dam DAM may be disposed to cover the top or the upper portions of four subpixels. Referring to FIG. 14, the dam DAM may cover four subpixels, and a contact hole CNT may be disposed in an area where the pixel electrode E1 and the second gate metal M2 contact. That is, referring to FIG. 14, the dam DAM may include four holes corresponding to four contact holes CNT.

For example, the substrate SUB may include a first subpixel and a second subpixel. A first contact hole CNT of the first subpixel and a second contact hole CNT of the second subpixel may be disposed on the substrate SUB. The dam DAM may be disposed to surround the first contact hole CNT and the second contact hole CNT.

Referring to FIG. 15, the dam DAM may be disposed beyond the area overlapping the second gate metal M2 on the passivation layer PAS. Referring to FIG. 15, the light blocking layer LS is shown extending to the right, and the dam DAM may also be disposed to extend to the right.

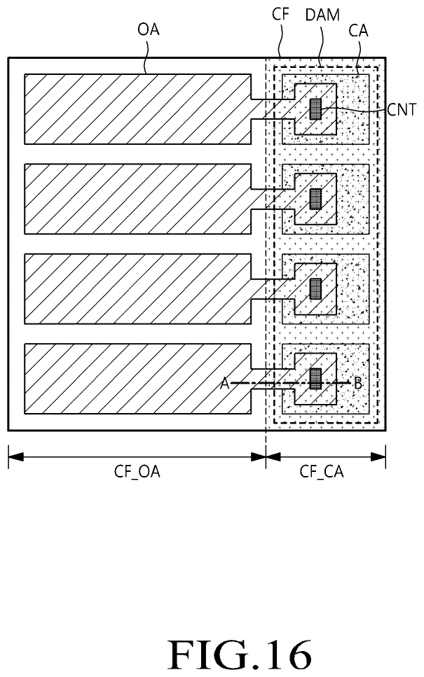

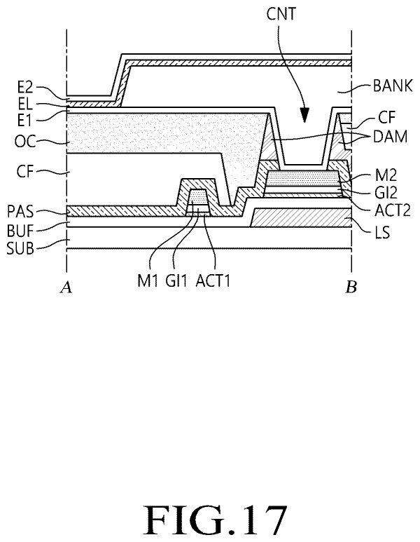

FIG. 16 is a plan view of a subpixel according to embodiments of the present disclosure. FIG. 17 is a cross-sectional view of the area AB according to embodiments of the present disclosure.

Referring to FIG. 16, the color filter layer CF may include a first color filter layer portion CF_OA disposed in the opening area OA and a second color filter layer portion CF_CA disposed in the circuit area CA. The color filter layer CF may be disposed in an area excluding the contact hole CNT where the pixel electrodes E1 of the four subpixels are disposed. The second color filter layer portion CF_CA may be disposed to surround the dam DAM. The second color filter layer portion CF_CA may be disposed in contact with the dam DAM. In addition, in order to stably prevent the second color filter layer portion CF_CA from overflowing into the contact hole CNT, the second color filter layer portion CF_CA may be disposed at a specific distance from the dam DAM.

Referring to FIG. 16, the second color filter layer portion CF_CA may include four holes. In the second color filter layer portion CF_CA, four holes may be located corresponding to four contact holes CNT.

Referring to FIG. 16, the second color filter layer portion CF_CA may be disposed in the circuit area CA. When the second color filter layer portion CF_CA is disposed in the circuit area CA, the second color filter layer portion CF_CA disposed in the circuit area CA may prevent parasitic capacitance from occurring between circuits disposed above and below the second color filter layer portion CF_CA.

Referring to FIG. 16, there is illustrated the area A-B in the plan view shown in FIG. 16. FIG. 17 shows a cross-sectional view of the area A-B. Referring to FIG. 17, the color filter layer CF may be disposed around the dam DAM. The dam DAM may be disposed in contact with the color filter layer CF. The color filter layer CF may be disposed to cover a portion of the dam DAM. Referring to FIG. 17, the dam DAM may include a portion disposed flat in the circuit area CA, and a portion disposed to surround the contact hole CNT. For example, a dam DAM may be formed using a halftone mask. The process using a halftone mask may be a process in which different layers are formed using one mask. After a flat portion of the dam DAM is formed, there may be formed a portion of the dam DAM surrounding the contact hole CNT.

In addition, a halftone mask may be used when forming a single layer. In this case, the single layer may be formed to have different thicknesses for each location. That is, a differential structure may be formed so that the thickness is different for each location of the corresponding layer. When forming a differential structure, a height of the dam DAM may be increased while preventing the occurrence of parasitic capacitance through the flatly disposed area. That is, since the dam DAM includes a portion disposed flat in the circuit area CA and a portion disposed to surround the contact hole CNT, it is possible to prevent the color filter CF from flowing into the hole CNT when forming the color filter CF. In addition, the color filter CF may be disposed on a flat portion of the dam DAM, and the color filter CF may prevent parasitic capacitance formed between the top and bottom of the color filter CF. Additionally, the overcoat layer OC may be disposed on the color filter CF, and the overcoat layer OC may also prevent parasitic capacitance formed between the top and bottom of the overcoat layer OC.

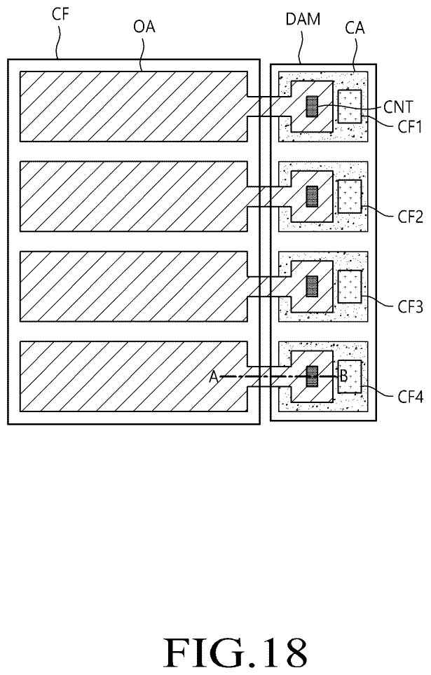

FIG. 18 is a plan view of a subpixel according to embodiments of the present disclosure.

Referring to FIG. 18, the circuit area included in the four subpixels may include a repair area. Repair means fixing a broken subpixel by disconnecting or connecting the circuit configuration of the transistor. The repair area may be an area where a data line is placed, an area where a reference voltage line is disposed, an area where an active layer of a driving transistor is placed, etc. For example, the repair area may correspond to the active layer area of the driving transistor, and this will be described below as an example.

Since the repair area is required to be visible from the outside, a layer overlapping the repair area may include hole areas which are etched and removed. If the layers overlapping the repair area include holes in the repair area, the repair area may be accurately identified. The operator can perform the repair process by checking the repair area.

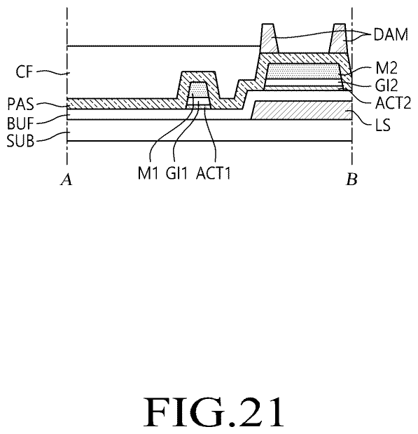

Referring to FIG. 18, one dam DAM may be disposed to cover the circuit area CA of four subpixels, as shown in FIG. 15. Referring to FIG. 21, a dam DAM may include eight holes.

Four of the eight holes of the dam DAM may correspond to four contact holes CNT. The four holes described above may be holes through which the pixel electrode E1 can be electrically connected to the driving transistor. The sub-contact holes, which are remaining four holes among the eight holes of the dam DAM, may correspond to the repair area of the driving transistor DRT. The four holes described above may be used to ensure that the repair area is clearly visible. This may be referred to as a sub-contact hole. Referring to FIG. 18, the dam DAM may further include a sub-contact hole in addition to the contact hole CNT where the pixel electrode E1 and the second gate metal M2 are in contact. The sub-contact hole area may be an area for repairing a portion of the circuit area CA. For example, the sub-contact hole area may correspond to an area for repairing the driving transistor DRT.

Meanwhile, since the sub-contact holes exist in the repair area, the repair area may be more susceptible to parasitic capacitance than other areas. To prevent this, a color filter layer may be disposed in the sub-contact hole. Referring to FIG. 21, the dam DAM may include four sub-contact holes, and the color filter layer may be disposed in the sub-contact hole area. The color filter layer may be formed inside the sub-contact hole area. Additionally, the color filter layer may be disposed to cover the sub-contact hole area. Accordingly, there may be reduced the influence of parasitic capacitance on the repair area.

Referring to FIG. 21, a first color filter layer CF1 may be disposed in a first sub-contact hole area. A second color filter layer CF2 may be disposed in a second sub-contact hole area. A third color filter layer CF3 may be disposed in a third sub-contact hole area. A fourth color filter layer CF4 may be disposed in a fourth sub-contact hole area. However, the color filter layer may be disposed only in some repair areas, or may not be disposed in the repair areas. That is, the color filter layer disposed in the repair area may be selectively provided according to design.

Hereinafter, it will be briefly described the process for forming the area AB.

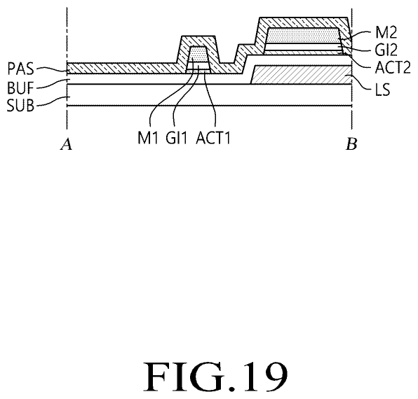

FIGS. 19 to 23 are diagrams for explaining a subpixel forming process according to embodiments of the present disclosure.

Referring to FIG. 19, the substrate SUB may be disposed at the bottom of the display panel 110. The light blocking layer LS may be disposed on the substrate SUB. The buffer layer BUF may be disposed to cover the substrate SUB and the light blocking layer LS. The first active metal ACT1 may be disposed on the buffer layer BUF. The second active metal ACT2 may be disposed on the buffer layer BUF. The first gate insulating layer GI1 may be disposed on the first active metal ACT1. The second gate insulating layer GI2 may be disposed on the second active metal ACT2. The first gate metal M1 may be disposed on the first gate insulating layer GI1. The second gate metal M2 may be disposed on the second gate insulating layer GI2. The passivation layer PAS may be disposed to cover the first gate metal M1 and the second gate metal M2.

Referring to FIG. 19, the second gate metal M2 may be a metal electrically connected to the second node N2, which is the source node of the driving transistor DRT. Although not shown in FIG. 19, the driving transistor DRT may include a first node N1 as a gate node and a third node N3 as a drain node, and a second node N2 as a source node of the driving transistor DRT may be electrically connected to the second gate metal M2.

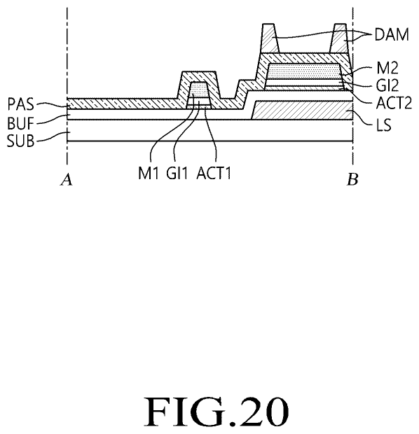

Referring to FIG. 20, the dam DAM may be disposed on the passivation layer PAS. The dam DAM on the passivation layer PAS may be disposed in an area overlapping with the second active metal ACT2 or the second gate metal M2 from a plan view. The dam DAM may have a shape in which a central area is carved out.

Referring to FIG. 21, the color filter layer CF may be disposed on the passivation layer PAS. The color filter layer CF on the passivation layer PAS may be disposed to overlap with the first gate metal M1. The color filter layer CF may be disposed in contact with the dam DAM.

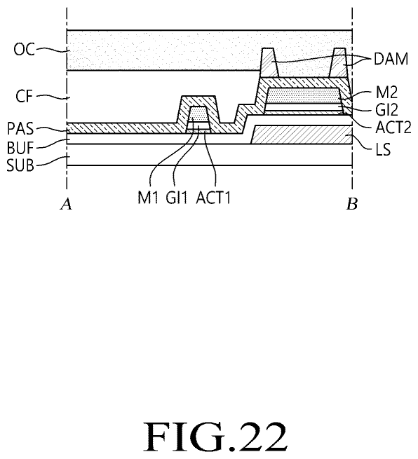

Referring to FIG. 22, the overcoat layer OC may be disposed to cover the color filter layer CF, the dam DAM, and the passivation layer PAS.

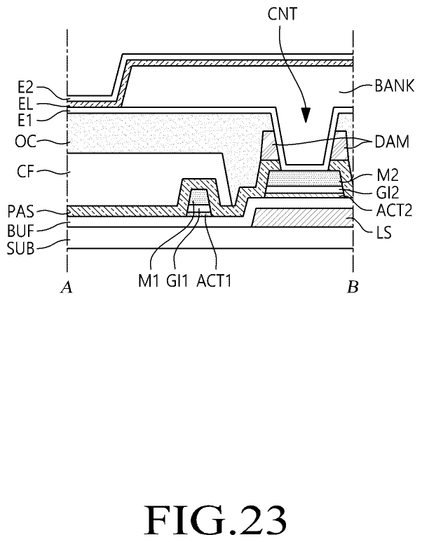

Referring to FIG. 23, a contact hole CNT may be formed through an etching process. Thereafter, the pixel electrode E1 may be disposed on the overcoat layer OC. The bank layer BANK may be disposed on the pixel electrode E1. The emission layer EL may be disposed on the pixel electrode E1.

Embodiments of the present disclosure described above are briefly described as follows.

A display device according to embodiments of the present disclosure may include a substrate, a first metal on the substrate, a passivation layer on the first metal, a dam on the passivation layer, and a contact hole extending into (in some embodiments, extending through and penetrating) the dam and the passivation layer.

The display device according to embodiments of the present disclosure may further include a color filter layer disposed on the passivation layer, and the dam may be disposed to be spaced apart from the color filter layer.

The display device according to embodiments of the present disclosure may further include a driving transistor disposed on the substrate. The driving transistor may include a first node electrode which are gate electrodes, a second node electrode, and a third node electrode, and the dam may be disposed on the first metal electrically connected to the second node electrode or the third node electrode of the driving transistor.

The display device according to embodiments of the present disclosure may further include a light blocking layer disposed on the substrate, a buffer layer disposed on the light blocking layer, an active layer disposed on the buffer layer, and a second insulating layer disposed between the first metal and the active layer.

The display device according to embodiments of the present disclosure may further include a pixel electrode disposed in the contact hole and in contact with the first metal, a bank disposed on the pixel electrode, an emission layer disposed on the bank, and a common electrode disposed on the emission layer.

The display device according to embodiments of the present disclosure may further include a pixel electrode disposed in the contact hole and in contact with the first metal, an emission layer disposed on the pixel electrode corresponding to the contact hole, and a common electrode disposed on the emission layer.

The display device according to embodiments of the present disclosure may further include an overcoat layer disposed to cover the dam, and the dam may include a different material from the overcoat layer.

The dam may include a side surface SS and an upper surface US, the display device may further include a pixel electrode disposed in contact with at least a portion of the upper surface of the dam.

The pixel electrode may be disposed to cover the dam.

The display device according to embodiments of the present disclosure may further include an overcoat layer disposed to cover the dam, and at least one material included in the dam may be included in the overcoat layer.

The contact hole CNT may include an area extending from a side surface SS of the dam DAM to a side surface SSS of the passivation layer PAS.

The display device according to embodiments of the present disclosure may further include a color filter layer disposed around the dam.

The substrate may include an opening area and a circuit area which is different from the opening area, and the color filter layer may be disposed in the circuit area.

The substrate may include a first subpixel and a second subpixel. The first subpixel may include a first contact hole, and the second subpixel may include a second contact hole. The dam may be disposed to surround the first contact hole and the second contact hole.

The display device according to embodiments of the present disclosure may further include a color filter layer disposed to cover at least a portion of the dam, and the color filter layer may be disposed to surround the first contact hole and the second contact hole on the dam.

The dam may include a plurality of sub-contact holes, and the display device may further include a color filter layer disposed within the plurality of sub-contact holes.

According to embodiments of the present disclosure, it is possible to provide a display device including a contact hole with stable contact characteristics.

According to embodiments of the present disclosure, it is possible to provide a display device including a color filter layer which does not overflow into the contact hole.

According to embodiments of the present disclosure, it is possible to provide a display device including a dam capable of preventing flooding of the color filter layer.

According to embodiments of the present disclosure, it is possible to provide a display device capable of low power consumption due to stable contact of the contact hole.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a first metal on the substrate;
a passivation layer on the first metal;
a dam on the passivation layer; and
a contact hole extending through the dam and the passivation layer.

2. The display device of claim 1, further comprising a color filter layer disposed on the passivation layer,
wherein the dam is disposed to be spaced apart from the color filter layer.

3. The display device of claim 1, further comprising a driving transistor disposed on the substrate,
wherein the driving transistor includes a first node electrode which are gate electrodes, a second node electrode, and a third node electrode, and
wherein the dam is disposed on the first metal electrically connected to either the second node electrode or the third node electrode of the driving transistor.

4. The display device of claim 1, further comprising:
a light blocking layer disposed on the substrate;
a buffer layer disposed on the light blocking layer;
an active layer disposed on the buffer layer; and
a second insulating layer disposed between the first metal and the active layer.

5. The display device of claim 1, further comprising:
a pixel electrode disposed in the contact hole and in contact with the first metal;
a bank disposed on the pixel electrode;
an emission layer disposed on the bank; and
a common electrode disposed on the emission layer.

6. The display device of claim 1, further comprising:
a pixel electrode disposed in the contact hole and in contact with the first metal;
an emission layer disposed on the pixel electrode corresponding to the contact hole; and
a common electrode disposed on the emission layer.

7. The display device of claim 1, further comprising an overcoat layer disposed to cover the dam,
wherein the dam includes a different material from the overcoat layer.

8. The display device of claim 7, wherein the dam includes a side surface and an upper surface, and
wherein the display device further comprises a pixel electrode disposed in contact with at least a portion of an upper surface of the dam.

9. The display device of claim 7, wherein the pixel electrode is disposed to cover the dam.

10. The display device of claim 1, further comprising an overcoat layer disposed to cover the dam,
wherein at least one material included in the dam is included in the overcoat layer.

11. The display device of claim 10, wherein the contact hole includes an area extending from a side surface of the dam to a side surface of the passivation layer.

12. The display device of claim 1, further comprising a color filter layer disposed around the dam.

13. The display device of claim 12, wherein the substrate includes an opening area and a circuit area which is different from the opening area, and
wherein the color filter layer is disposed in the circuit area.

14. The display device of claim 1, wherein the substrate includes a first subpixel and a second subpixel,
wherein the first subpixel includes a first contact hole, and the second subpixel includes a second contact hole, and
wherein the dam is disposed to surround the first contact hole and the second contact hole.

15. The display device of claim 14, further comprising a color filter layer disposed to cover at least a portion of the dam,
wherein the color filter layer is disposed to surround the first contact hole and the second contact hole on the dam.

16. The display device of claim 14, wherein the dam includes a plurality of sub-contact holes, and
wherein the display device further comprises a color filter layer disposed within the plurality of sub-contact holes.
